(19) United States
(12) Patent Application Publication
(10) Pub. No.: US 2011/0114475 A1
(43) Pub. Date: May 19, 2011

(54) METHOD FOR PRODUCING TRANSPARENT CONDUCTIVE FILM

(76) Inventor: Akira Hasegawa, Ibaraki (JP)

(21) Appl. No.: 13/000,767

(22) PCT Filed: Jun. 22, 2009
(86) PCT No.: PCT/JP2009/061793

§ 371 Date: Dec. 22, 2010

(30) Foreign Application Priority Data
Jun. 25, 2008 (JP) 2008-165411

(51) Int. Cl. C23C 14/34; C23C 14/08

(52) U.S. Cl. 204/192.29

(57) ABSTRACT

Disclosed herein is a method for producing a transparent conductive film. The method for producing a transparent conductive film comprises a step of forming a transparent conductive film on a support by a physical film-forming method using a sintered body as a target in a mixed gas atmosphere, wherein the sintered body contains Zn, Sn, and O, and the mixed gas contains an inert gas and oxygen and has an oxygen concentration of 0.01 vol % or higher and 0.4 vol % or less.

### TECHNICAL FIELD

The present invention relates to a method for producing a transparent conductive film.

### BACKGROUND ART

Transparent conductive films are used as, for example, electrodes for displays such as liquid crystal displays, organic EL displays, and plasma displays, electrodes for solar cells, heat reflecting films for window panes, and antistatic films. As such transparent conductive films, ITO films (In₂O₃—SnO₂-based films) are well-known. Since In is a rare metal, transparent conductive film having a low In content is demanded. As such transparent conductive films, ZnO—SnO₂-based films are known. JP8-171824A describes a technique for obtaining a transparent conductive film made of Zn₂SnO₄ or ZnSnO₃ by sputtering using, as a target, a calcined powder yielded by mixing and calcining ZnO and SnO₂.

### DISCLOSURE OF THE INVENTION

Transparent conductive films produced by conventional techniques have had still room for improvement in their film characteristics such as conductivity, and their film characteristics have not yet been on such a level that the films can substitute for ITO films. It is therefore an object of the present invention to provide a method for producing a transparent conductive film in which an In content can be reduced and film characteristics, such as conductivity, can be improved on such a level that the film is comparable to an ITO film.

In order to achieve the above object, the present inventors have extensively studied, and as a result, the present invention has completed.

The present invention provides the followings.

<1> A method for producing a transparent conductive film, the method comprising a step of forming a transparent conductive film on a support by a physical film-forming method using a sintered body as a target in a mixed gas atmosphere, wherein

the sintered body contains Zn, Sn, and O, and

the mixed gas contains an inert gas and oxygen and has an oxygen concentration of 0.01 vol % or higher and 0.4 vol % or less.

<2> The method according to <1>, wherein the physical film-forming method is sputtering.
<3> The method according to <1> or <2>, wherein the sintered body contains Zn, Sn, and O and has a molar ratio of Sn to a sum of Sn and Zn (Sn/(Sn+Zn)) of higher than 0.5 and less than 0.7.
<4> The method according to <3>, wherein the sintered body has a crystal structure including a mixed phase of spinel-type Zn₂SnO₄ and rutile-type SnO₂.
<5> The method according to <3> or <4>, wherein the transparent conductive film has a resistivity of less than 3×10⁻³ Ω·cm.
<6> The method according to any one of <1> to <5>, wherein the temperature of the support is 100° C. or higher and 300° C. or less.
<7> The method according to any one of <1> to <6>, wherein the transparent conductive film is an amorphous film.

### MODE FOR CARRYING OUT THE INVENTION

### Method for Producing Transparent Conductive Film

The method for producing a transparent conductive film according to the present invention is a method for producing a transparent conductive film, the method comprising a step of forming a transparent conductive film on a support by a physical film-forming method using a sintered body as a target in a mixed gas atmosphere, wherein

the sintered body contains Zn, Sn, and O, and

the mixed gas contains an inert gas and oxygen and has an oxygen concentration of 0.01 vol % or higher and 0.4 vol % or less.

The sintered body contains Zn, Sn, and O, and usually contains Zn, Sn, and O as main components. More specifically, this means that the ratio of the total molar amount of Zn and Sn to the total molar amount of all the metal elements contained in the sintered body is 0.95 or higher. According to the present invention, the sintered body can contain, as a doping element, a metal element other than Zn and Sn as long as the effects of the present invention are not impaired. Examples of such a doping element include Al, Sb, and In. Further, from the viewpoint of minimizing the In content of a resulting transparent conductive film, the preferable sintered body is a sintered body composed of Zn, Sn, and O, and more specifically, the sintered body containing Zn, Sn, O, and substantially no other metal elements. Examples of the other metal elements include Al, Sb, and In, and the content thereof is usually less than 0.1 wt %.

This is not intended to exclude a residue (e.g., carbon or halogen) derived from an additive, such as a binder, used for producing a sintered body, which will be described later. The sintered body contains an oxide containing Zn, Sn, and O.

As regards the composition ratio between Zn and Sn of the sintered body, the molar ratio of Sn to the sum of Sn and Zn (Sn/(Sn+Zn), hereinafter also referred to as “Sn composition ratio”) is preferably higher than 0.5 and less than 0.7, more preferably higher than 0.55 and less than 0.7. By setting the Sn composition ratio to a value higher than 0.55 and less than 0.7, a transparent conductive film having a resistivity (Ω·cm) of less than 3×10⁻³ can be obtained. The Sn composition ratio is more preferably higher than 0.6 and less than 0.7. The Sn composition ratio within the above range is more preferably applied to a case where the sintered body is composed of Zn, Sn, and O. When the Sn composition ratio is within the above range, a transparent conductive film which has superior etching properties and is amorphous can be easily obtained. Such a transparent conductive film is more suitable for, for example, flexible displays and touch screens. In the present invention, the oxygen concentration (vol %) of the mixed gas is 0.01 or higher and 0.4 or less, which makes it possible to yield a transparent conductive film having a low resistivity. The oxygen concentration (vol %) of the mixed gas is preferably 0.1 or higher and 0.3 or less.

Further, according to the present invention, an amorphous film can be obtained. In a case where an amorphous film is subjected to XRD measurement, any peaks indicating the film being crystalline can not be detected, and even when a peak is detected, only a halo indicating the film being amorphous can be detected.

Hereinbelow, the present invention will be described more specifically.

First, a zinc-containing compound, a tin-containing compound, and, if necessary, a doping element-containing compound are weighed in prescribed amounts and mixed to yield a mixture. The mixture is molded and then sintered to yield a sintered body. Alternatively, the mixture can be calcined to yield an oxide powder. In this case, the oxide powder is pulverized if necessary, molded, and then sintered to yield a sintered body. The composition ratio (molar ratio) among Zn, Sn, and a doping element, which is used if necessary, of the mixture is reflected in the composition ratio among them of a resultant sintered body. The mixture can be pre-calcined before calcination and can be pulverized after pre-calcination.

Examples of the zinc-containing compound include zinc oxide, zinc hydroxide, zinc carbonate, zinc nitrate, zinc sulfate, zinc phosphate, zinc pyrophosphate, zinc chloride, zinc fluoride, zinc iodide, zinc bromide, zinc carboxylates (e.g., zinc acetate and zinc oxalate), basic zinc carbonate, zinc alkoxides, and hydrated salts thereof. Among them, powdery zinc oxide is preferred from the viewpoint of handleability. Examples of the tin-containing compound include tin oxides (SnO₂, SnO), tin hydroxide, tin nitrate, tin sulfate, tin chloride, tin fluoride, tin iodide, tin bromide, tin carboxylates (e.g., tin acetate and tin oxalate), tin alkoxides, and hydrated salts thereof. Among them, powdery tin oxide (especially, SnO₂) is preferred from the viewpoint of handleability. Examples of the doping element-containing compound include doping element-containing oxide, hydroxide, carbonate, nitrate, sulfate, phosphate, pyrophosphate, chloride, fluoride, iodide, bromide, carboxylates (e.g., acetate and oxalate), alkoxides, and hydrated salts thereof. Among them, a powdery oxide is preferred from the viewpoint of handleability. These compounds preferably have purity as high as possible. More specifically, these compounds preferably have a purity of 99 wt % or higher.

The above-mentioned mixing can be performed by either a dry mixing method or a wet mixing method. Usually, mixing is performed simultaneously with pulverization. More specifically, the zinc-containing compound, the tin-containing compound, and if necessary, the doping element-containing compound are preferably mixed by a method in which they can be more uniformly mixed. Examples of the mixing apparatus include ball mills, vibration mills, attritors, dyno-mills, and dynamic mills. After mixing, drying can be performed by, for example, heat drying (stationary drying, spray drying), vacuum drying, or freeze drying.

In the case where the doping element is contained, a water-soluble compound can be used as the doping element-containing compound, and an aqueous solution of the water-soluble compound can be mixed with a mixed powder of the zinc-containing compound and the tin-containing compound and then these can be, if necessary, dried to yield a mixture. Alternatively, a compound soluble in an organic solvent such as ethanol can be used as the doping element-containing compound. In this case, a solution obtained by dissolving the organic solvent-soluble compound in an organic solvent can be used instead of the aqueous solution. By calcining or sintering the thus obtained mixture, an oxide containing Zn, Sn, and O as main components and having higher uniformity of a doping element can be obtained.

A mixture obtained by coprecipitation can be used. As the zinc-containing compound, the tin-containing compound, and, if necessary, the doping element-containing compound, water-soluble compounds are respectively used, for example, and a mixed aqueous solution of these compounds is prepared, and then a coprecipitation is performed to yield a coprecipitate in which a precipitating agent such as an alkali and the mixed aqueous solution are used. The coprecipitate can be dried if necessary, and can be used as a mixture. By calcining or sintering the thus obtained mixture, an oxide containing Zn, Sn, and O as main components and having higher uniformity of constituent elements and higher uniformity of a doping element can be obtained.

The above-mentioned molding can be performed by, for example, uniaxial pressing, cold isostatic pressing (CIP), or a combination of them, in which cold isostatic pressing (CIP) is performed after uniaxial pressing. The molding pressure is usually in the range of 100 to 3000 kgf/cm². Cold isostatic pressing (CIP) is preferably performed because a green body having a higher density can be obtained and a sintered body having a higher density can be obtained, whereby the resistivity of a resulting transparent conductive film can be lowered. A green body obtained by molding is usually in the form of a disk or a rectangular plate. The mixture can contain a binder, a dispersing agent, a releasing agent or the like when molded.

The above-mentioned sintering is performed by keeping a green body obtained by the above-mentioned molding in an oxygen-containing atmosphere such as air at a temperature of 1150° C. or higher and 1350° C. or less as a maximum reaching temperature for 0.5 to 48 hours. Examples of a sintering apparatus include furnaces usually used in industrial applications such as electric furnaces and gas furnaces. A sintered body obtained by sintering can be subjected to cutting or grinding for size adjustment. Alternatively, the size adjustment can be performed by cutting or grinding a green body which can be more easily processed than a sintered body. Molding and sintering can be performed simultaneously by, for example, hot pressing or hot isostatic pressing (HIP) instead of the above-mentioned molding and sintering. Particularly, when a sintered body does not contain a doping element, that is, a sintered body is composed of Zn, Sn, and O, the sintered body obtained by sintering, which is performed by keeping the above-mentioned maximum reaching temperature at a temperature of 1150° C. or higher and 1350° C. or less, has a crystal structure comprising a mixed phase of spinel-type Zn₂SnO₄ and rutile-type SnO₂. From the viewpoint of obtaining a transparent conductive film having a lower resistivity, a target for producing a transparent conductive film is preferably constituted from the thus obtained sintered body.

The above-mentioned calcining can be performed by keeping a mixture in an oxygen-containing atmosphere such as air at a temperature of 1150° C. or higher and 1350° C. or less as a maximum reaching temperature for 0.5 to 48 hours. Examples of a calcining apparatus include furnaces usually used in industrial applications such as electric furnaces and gas furnaces. In a case where, after calcining, pulverization is performed if necessary, and then molding and sintering are performed, the maximum reaching temperature during calcining is preferably set to be lower than that during sintering. The pulverization performed if necessary after calcining can be performed in the same manner as described above with reference to the above-mentioned mixing process. Also in this case, a pulverized product can contain a binder, a dispersing agent, a releasing agent or the like when molded. When pre-calcination is performed before calcining, the maximum reaching temperature during pre-calcination is preferably lower than that during calcining. If necessary, pulverization can be performed after pre-calcination.

Examples of the physical film-forming method used in the present invention include pulse laser vapor deposition (laser ablation), sputtering, ion plating, and EB vapor deposition. Among these film-forming methods, sputtering is preferred from the viewpoint of versatility of a film-forming apparatus. The temperature of a support used in such a physical film-forming method is preferably 100° C. or higher and 300° C. or less, which makes it possible to easily obtain an amorphous film.

In a case where sputtering is employed to form a transparent conductive film, a transparent conductive film is formed on a support by sputtering using, as a sputtering target, a sintered body obtained in such a manner as described above and containing Zn, Sn, and O as main components. At this time, a mixed gas of an inert gas and oxygen, the mixed gas having an oxygen concentration (vol %) of 0.01 or higher and 0.4 or less, is used as the sputtering atmosphere. A metal chip target can be used together with the sputtering target without departing from the scope of the present invention. In this case, examples of the metal chip include a Zn chip, an Sn chip, and a metal chip that consists of a doping element. The pressure of the atmosphere within a chamber during sputtering is usually about 0.1 to 10 Pa. As a sputtering apparatus, an rf magnetron sputtering apparatus can be used. As regards conditions when using an rf magnetron sputtering apparatus, conditions at an rf input power of 10 to 300 W and a pressure of about 0.1 to 1 Pa can be recommended. The inert gas contained in the mixed gas can include argon gas. In a mixed gas, the concentration of a gas other than an inert gas and oxygen is preferably as low as possible.

In the present invention, the support refers to an object on which a film is to be formed. Examples of such a support, which can be used, include glass substrates, quartz glass substrates, and plastic substrates. When a transparent conductive film is used as a transparent electrode, the support is preferably transparent. The support can be a crystalline substrate. Examples of such a crystalline substrate include substrates made of Al₂O₃ (sapphire), MgO, YSZ(ZrO₂—Y₂O₃), CaF₂, or SrTiO₃. If necessary, a resulting transparent conductive film can be subjected to heat treatment.

### EXAMPLES

Hereinbelow, the present invention will be described more specifically with reference to the following examples. It is to be noted that the electric characteristics, optical characteristics, and crystal structure of the obtained films were evaluated by the following methods unless otherwise specified.

The evaluations of the electric characteristics were performed by determining the resistivity of the film according to the following formula (I), in which the surface resistance (sheet resistance) of a film was measured by a four-probe method in accordance with JIS R 1637, the thickness of the film was measured by a stylus film thickness meter and the measured values of surface resistance and film thickness were used.

Resistivity (Ωcm)=surface resistance (Ω/□)×film thickness (cm) (1)

The evaluations of the optical characteristics were performed by measuring visible-light transmittance by a method specified in JIS R 1635 using a visible spectrophotometer.

The evaluations of the crystal structure of a film and a sintered body were performed by identifying the crystal type thereof using a powder X-ray diffraction apparatus (“RINT2500TTR” manufactured by Rigaku Corporation) in which a film or a sintered body was irradiated with CuKa light to obtain an X-ray diffraction pattern.

### Example 1

A zinc oxide powder (ZnO manufactured by Kojundo Chemical Lab. Co., Ltd., purity: 99.99%) and a tin oxide powder (SnO₂ manufactured by Kojundo Chemical Lab. Co., Ltd., purity: 99.99%) were weighed so that the molar ratio of Sn to the sum of Zn and Sn (Sn/(Zn+Sn)) was 0.67, and were then mixed together by dry ball milling using zirconia balls having a diameter of 5 mm. The resulting mixed powder was placed in an alumina crucible and calcined by keeping it in an air atmosphere at 900° C. for 5 hours, and was then further pulverized by dry ball milling using zirconia balls having a diameter of 5 mm. The resulting powder was molded into a disk by uniaxial pressing at a pressure of 500 kgf/cm² using a mold. Then, the green body was subjected to cold isostatic pressing (CIP) at a pressure of 2000 kgf/cm², and was then sintered by keeping it in an oxygen atmosphere at 1200° C. under normal pressure for 5 hours to yield a sintered body. The sintered body was analyzed by X-ray diffraction, and as a result, it was found that the sintered body had a crystal structure including a mixed phase of spinel-type Zn₂SnO₄ and rutile-type SnO₂. It is to be noted that the crystal structure of ZnSnO₃ was not detected. The molar ratio of Zn₂SnO₄:SnO₂ of the sintered body determined based on these results was 1:3. Then, the sintered body was processed into a sputtering target having a diameter of 3 inches, and was placed in a sputtering apparatus (CFS-4ES-231 manufactured by Tokuda Seisakusho Co., Ltd.). Further, a glass substrate used as a support was also placed in the sputtering apparatus. Sputtering was performed in a mixed gas of argon and oxygen (oxygen concentration: 0.1 vol %) under conditions where the pressure was 0.5 Pa, the temperature of the substrate was 265° C., and the power was 50 W to yield a transparent conductive film formed on the substrate. The thus obtained transparent conductive film had a resistivity of 1.9×10⁻³ Ωcm. The transmittance of the glass substrate having the transparent conductive film formed thereon was measured, and as a result, it was found that its maximum visible-light transmittance was higher than 80%. The resulting transparent conductive film was analyzed by X-ray diffraction and found to be amorphous.

### Example 2

A transparent conductive film formed on a substrate was yielded in the same manner as in Example 1 except that the sputtering atmosphere was changed to a mixed gas of argon and oxygen (oxygen concentration: 0.2 vol %). The thus obtained film had a resistivity of 2.8×10⁻³ Ωcm. The transmittance of the glass substrate having the transparent conductive film formed thereon was measured, and as a result, it was found that its maximum visible-light transmittance was higher than 80%. The resulting transparent conductive film was analyzed by X-ray diffraction and found to be amorphous.

### Example 3

A transparent conductive film formed on a substrate was yielded in the same manner as in Example 1 except that the sputtering atmosphere was changed to a mixed gas of argon and oxygen (oxygen concentration: 0.3 vol %). The thus obtained film had a resistivity of 2.6×10⁻³ Ωcm. The transmittance of the glass substrate having the transparent conductive film formed thereon was measured, and as a result, it was found that its maximum visible-light transmittance was higher than 80%. The resulting transparent conductive film was analyzed by X-ray diffraction and found to be amorphous.

### Comparative Example 1

A transparent conductive film formed on a substrate was yielded in the same manner as in Example 1 except that the sputtering atmosphere was changed to a mixed gas of argon and oxygen (oxygen concentration: 0.5 vol %). The thus obtained film had a resistivity of 1.1×10⁻² Ωcm. The transmittance of the glass substrate having the transparent conductive film formed thereon was measured, and as a result, it was found that its maximum visible-light transmittance was higher than 80%. The resulting transparent conductive film was analyzed by X-ray diffraction and found to be amorphous.

### Comparative Example 2

A zinc oxide powder (ZnO manufactured by Kojundo Chemical Lab. Co., Ltd., purity: 99.99%) and a tin oxide powder (SnO₂ manufactured by Kojundo Chemical Lab. Co., Ltd., purity: 99.99%) were weighed so that the molar ratio of Sn to the sum of Zn and Sn (Sn/(Zn+Sn)) was 0.50, and were then mixed together by dry ball milling using zirconia balls having a diameter of 5 mm. The resulting mixed powder was placed in an alumina crucible and calcined by keeping it in an air atmosphere at 900° C. for 5 hours, and was then further pulverized by dry ball milling using zirconia balls having a diameter of 5 mm. The resulting powder was molded into a disk by uniaxial pressing at a pressure of 500 kgf/cm² using a mold. Then, the green body was subjected to cold isostatic pressing (CIP) at a pressure of 2000 kgf/cm², and was then sintered by keeping it in an oxygen atmosphere at 1200° C. under normal pressure for 5 hours to yield a sintered body. Then, the sintered body was processed into a sputtering target having a diameter of 3 inches, and was placed in a sputtering apparatus (CFS-4ES-231 manufactured by Tokuda Seisakusho Co., Ltd.). Further, a glass substrate used as a support was also placed in the sputtering apparatus. Sputtering was performed in an argon gas atmosphere under conditions where the pressure was 0.5 Pa, the temperature of the substrate was 265° C., and the power was 50 W to yield a transparent conductive film formed on the substrate. The thus obtained transparent conductive film had a resistivity of 3.7×10⁻³ Ωcm. The transmittance of the glass substrate having the transparent conductive film formed thereon was measured, and as a result, it was found that its maximum visible-light transmittance was higher than 80%. The resulting transparent conductive film was analyzed by X-ray diffraction and found to be amorphous.

### INDUSTRIAL APPLICABILITY

According to the present invention, it is possible to provide a method for producing a transparent conductive film in which an expensive In content have been reduced and film characteristics, such as conductivity, have been improved on such a level that the film is comparable to an ITO film. Further, a transparent conductive film obtained by the method according to the present invention has superior etching properties, and is therefore suitably used as, for example, an electrode for displays such as liquid crystal displays, organic EL displays, and plasma displays, an electrode for solar cells, a heat reflecting film for windowpanes, or an antistatic film. Further, the method according to the present invention can also provide an amorphous film, and such an amorphous film is sufficiently applicable to, for example, flexible displays and touch screens.

1. A method for producing a transparent conductive film, the method comprising a step of forming a transparent conductive film on a support by a physical film-forming method using a sintered body as a target in a mixed gas atmosphere, wherein
the sintered body contains Zn, Sn, and O, and
the mixed gas contains an inert gas and oxygen and has an oxygen concentration of 0.01 vol % or higher and 0.4 vol % or less.

2. The method according to claim 1, wherein the physical film-forming method is sputtering.

3. The method according to claim 1 or 2, wherein the sintered body contains Zn, Sn, and O and has a molar ratio of Sn to a sum of Sn and Zn (Sn/(Sn+Zn)) of higher than 0.5 and less than 0.7.

4. The method according to claim 3, wherein the sintered body has a crystal structure comprising a mixed phase of spinel-type Zn₂SnO₄ and rutile-type SnO₂.

5. The method according to claim 3, wherein the transparent conductive film has a resistivity of less than 3×10⁻³ Ω·cm.

6. The method according to claim 1, wherein the temperature of the support is 100° C. or higher and 300° C. or less.

7. The method according to claim 1, wherein the transparent conductive film is an amorphous film.
